(19) United States
(12) Patent Application Publication
(10) Pub. No.: US 2021/0118863 A1
(43) Pub. Date: Apr. 22, 2021

(54) SEMICONDUCTOR APPARATUS

(71) Applicants: HONDA MOTOR CO., LTD., Tokyo (JP); TOKYO INSTITUTE OF TECHNOLOGY, Tokyo (JP)

(72) Inventors: Koji Sakui, Wako-shi (JP); Takayuki Ohba, Tokyo (JP)

(21) Appl. No.: 17/063,730

(22) Filed: Oct. 6, 2020

(30) Foreign Application Priority Data
Oct. 17, 2019 (JP) 2019-190110

(51) Int. Cl. H01L 25/18; H01L 25/065; H01L 23/00

(52) U.S. Cl. CPC H01L 25/18; H01L 25/0652; H01L 24/08; H01L 2924/1436; H01L 2224/08145; H01L 2924/1431; H01L 2225/06541

(57) ABSTRACT

A semiconductor apparatus includes a chip laminate body in which a plurality of memory chips are laminated on a logic chip that controls each of the plurality of memory chips, wherein the chip laminate body includes a plurality of penetration electrodes that penetrate through the plurality of memory chips and the logic chip in a thickness direction and includes a bumpless structure in which the plurality of memory chips and the logic chip are electrically connected together via the plurality of penetration electrodes without arranging a bump electrode in each space among the plurality of memory chips and the logic chip, and a conductance of a first transistor provided on the plurality of memory chips is smaller than a conductance of a second transistor provided on the logic chip.

### CROSS-REFERENCE TO RELATED APPLICATION

Priority is claimed on Japanese Patent Application No. 2019-190110, filed on Oct. 17, 2019, the contents of which are incorporated herein by reference.

### BACKGROUND

### Field of the Invention

The present invention relates to a semiconductor apparatus.

### Background

In recent years, a semiconductor apparatus called a HBM (High Bandwidth Memory) in which DRAM (Dynamic Random Access Memory) chips are laminated to enlarge a bandwidth and increase a speed has attracted attention.

Such a semiconductor apparatus includes a chip laminate body in which a plurality of DRAM chips are laminated on a logic chip (for example, refer to Japanese Unexamined Patent Application, First Publication No. 2005-210106, Japanese Unexamined Patent Application, First Publication No. 2007-157266, and Japanese Unexamined Patent Application, First Publication No. 2004-327474). The chip laminate body includes a plurality of penetration electrodes (TSV) that penetrate through the plurality of DRAM chips and the logic chip in a thickness direction and a bump electrode provided in each space among the plurality of DRAM chips and the logic chip. In the chip laminate body, the penetration electrodes are electrically connected together via the bump electrode.

However, in such a semiconductor apparatus, there is a problem of heat generation at the chip laminate body. A major factor of the heat generation is that since the plurality of DRAM chips and the logic chip are electrically connected together via the penetration electrode and the bump electrode, the electric resistance of the connection portion becomes extremely large.

In this case, it is necessary to increase the size of a transistor which is an input/output (I/O) buffer of the DRAM chip and drive the transistor using a large current, the electric power consumed by the transistor increases, and the DRAM chip generates heat. Accordingly, in the current HBM2, the number of laminations is limited to 4 chips, and the input/output I/O is limited to 1024 channels.

Further, in the DRAM chip, a leak current from a memory cell is larger at a higher temperature. Therefore, a reflex cycle is determined with respect to the leak current from the memory cell. That is, there is a very strong correlation between a retention time in which a memory is retained and the temperature and between a pause time and the temperature.

Accordingly, in the semiconductor apparatus, in a case where a temperature difference occurs between a DRAM chip on an upper layer side and a DRAM chip on a lower layer side, it is necessary to change a reflex cycle of the DRAM chip between the DRAM chip on the upper layer side and the DRAM chip on the lower layer side. This is the biggest problem in increasing the number of layers.

### SUMMARY

An object of an aspect of the present invention is to provide a semiconductor apparatus capable of increasing a lamination number of memory chips without changing a reflex cycle while reducing heat generation from a memory chip that constitutes a chip laminate body.

A semiconductor apparatus according to a first aspect of the present invention includes a chip laminate body in which a plurality of memory chips are laminated on a logic chip that controls each of the plurality of memory chips, wherein the chip laminate body includes a plurality of penetration electrodes that penetrate through the plurality of memory chips and the logic chip in a thickness direction and includes a bumpless structure in which the plurality of memory chips and the logic chip are electrically connected together via the plurality of penetration electrodes without arranging a bump electrode in each space among the plurality of memory chips and the logic chip, and a conductance of a first transistor provided on the plurality of memory chips is smaller than a conductance of a second transistor provided on the logic chip.

A second aspect of the present invention is the semiconductor apparatus according to the first aspect, wherein a ratio of the conductance of the first transistor to the conductance of the second transistor may be equal to or less than 1/3.

A third aspect of the present invention is the semiconductor apparatus according to the first aspect, wherein a ratio of the conductance of the first transistor to the conductance of the second transistor may be equal to or less than 1/10.

A fourth aspect of the present invention is the semiconductor apparatus according to any one of the first to third aspects, wherein a thickness of the chip laminate body may be 40 to 200 μm, a thickness of the memory chip may be 2 to 10 μm, and a thickness of the logic chip may be 2 to 20 μm.

A fifth aspect of the present invention is the semiconductor apparatus according to any one of the first to fourth aspects, wherein the memory chip may be a DRAM chip.

As described above, according to the aspect of the present invention, it is possible to provide a semiconductor apparatus capable of increasing the lamination number of memory chips without changing a reflex cycle while reducing heat generation from the memory chip that constitutes the chip laminate body.

### BRIEF DESCRIPTION OF THE DRAWINGS

FIG. 1 is a cross-sectional view showing a configuration of a semiconductor apparatus according to an embodiment of the present invention.

FIG. 2 is a perspective view showing a configuration of a chip laminate body included in the semiconductor apparatus shown in FIG. 1.

FIG. 3A is a circuit diagram showing a configuration of a first transistor provided on a logic chip.

FIG. 3B is a circuit diagram showing a configuration of a second transistor provided on a memory chip.

### DESCRIPTION OF THE EMBODIMENTS

Hereinafter, an embodiment of the present invention will be described in detail with reference to the drawings. In order to make the features easy to understand, a characterizing portion may be schematically shown in the drawings used in the following description for convenience, and the dimensional ratio or the like of each component is not necessarily the same as the actual dimensional ratio.

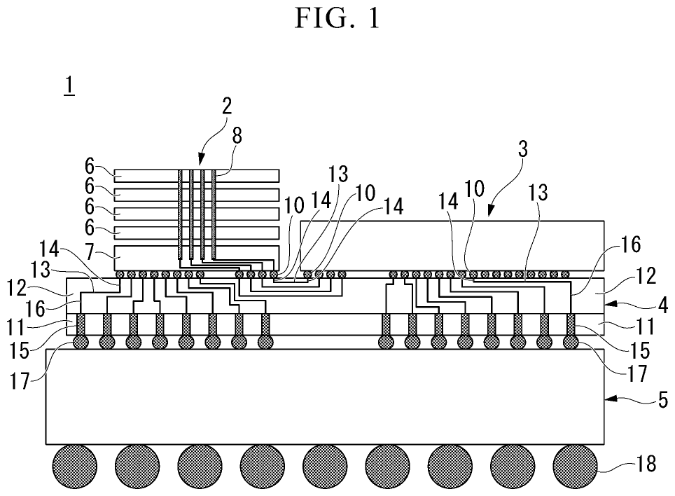

As an embodiment of the present invention, for example, a semiconductor apparatus 1 shown in FIG. 1 is described.

The semiconductor apparatus 1 of the present embodiment is a semiconductor package referred to as an HBM, as shown in FIG. 1 and includes a first semiconductor chip 2, a second semiconductor chip 3, an interposer 4 having one surface (an upper surface in the present embodiment) on which the first semiconductor chip 2 and the second semiconductor chip 3 are mounted, and a package substrate 5 having one surface (an upper surface in the present embodiment) on which the interposer 4 is mounted.

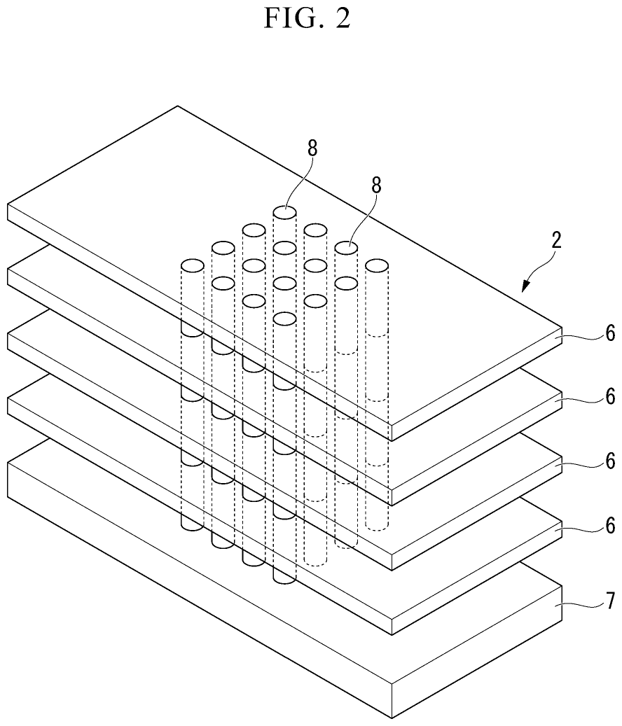

As shown in FIG. 2, the first semiconductor chip 2 is formed of a chip laminate body in which a plurality of (in the present embodiment, four) memory chips (DRAM chip) 6 on which, for example, a DRAM circuit or the like is formed are laminated on a logic chip 7 on which a logic circuit that controls each of the memory chips 6 or the like is formed.

The first semiconductor chip 2 includes a plurality of penetration electrodes (TSV) 8 that penetrate through each of the memory chips 6 and the logic chip 7 in a thickness direction. The first semiconductor chip 2 includes a bumpless structure in which the plurality of memory chips 6 and the logic chip 7 are electrically connected together via the penetration electrode 8 without arranging a bump electrode in each space among the plurality of memory chips 6 and the logic chip 7.

FIG. 1 and FIG. 2 are illustrated in a state where the memory chips 6 and the logic chip 7 are separated from each other; however, in reality, the chips 6, 7 are in direct contact with each other or in close contact with each other so as to interpose an interlayer (an adhesive layer or the like).

As shown in FIG. 1, the second semiconductor chip 3 controls the first semiconductor chip 2 and is formed of, for example, a host processor such as a CPU, a GPU, or a SoC. The first semiconductor chip 2 and the second semiconductor chip 3 are electrically connected to the interposer 4 via a plurality of bump electrodes 10 arrayed on a surface of the interposer 4.

The interposer 4 is formed of a multilayer wiring substrate, for example, in which a plurality of wiring layers 13 are laminated via an interlayer insulation layer 12 on a Si substrate 11. The wiring layer 13 and the bump electrode 10 are electrically connected together via a contact plug 14 that penetrates through the interlayer insulation layer 12 in a thickness direction. Thereby, the interposer 4 electrically connects the first semiconductor chip 2 to the second semiconductor chip 3.

The interposer 4 includes a penetration electrode (TSV) 15 that penetrates through the Si substrate 11 in a thickness direction. The wiring layer 13 and the penetration electrode (TSV) 15 are electrically connected together via a contact plug 16 that penetrates through the interlayer insulation layer 12 in a thickness direction.

The interposer 4 is electrically connected to the package substrate 5 via a plurality of bump electrodes 17 arrayed on a surface of the package substrate 5. The wiring layer 13 and the bump electrode 17 are electrically connected together via the penetration electrode (TSV) 15. Thereby, the interposer 4 electrically connects the first semiconductor chip 2 and the second semiconductor chip 3 to the package substrate 5.

The package substrate 5 is formed of a printed-circuit board (PCB) and includes a plurality of solder balls 18 referred to as a BGA (Ball Grid Array) on another surface (in the present embodiment, a lower surface) of the package substrate 5 as an external connection terminal.

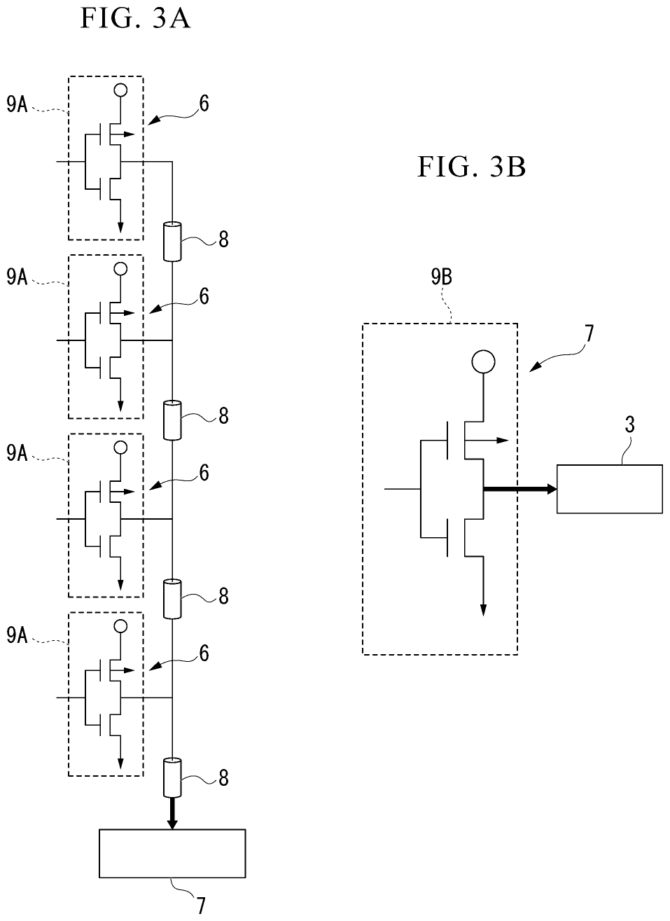

As shown in FIGS. 3A, 3B, in the semiconductor apparatus 1 of the present embodiment, the transistors 9A, 9B, which are input/output (I/O) buffers, are provided on the plurality of memory chips 6 and the logic chip 7, respectively.

Specifically, as shown in FIG. 3A, the first transistor 9A is provided on the memory chip 6. The first transistor 9A provided on each memory chip 6 is electrically connected to the logic chip 7 via the plurality of penetration electrodes 8.

On the other hand, as shown in FIG. 3B, the second transistor 9B is provided on the logic chip 7. The logic chip 7 is electrically connected to the second semiconductor chip 3 via the second transistor 9B.

In the semiconductor apparatus 1 of the present embodiment, the plurality of memory chips 6 and the logic chip 7 described above constitute the chip laminate body having a bumpless structure, and thereby, it is possible to reduce the electric resistance of the plurality of penetration electrodes 8 that electrically connect together the plurality of DRAM chips 6 and the logic chip 7.

Thereby, it is possible to make the conductance of the first transistor 9A provided on each memory chip 6 to be smaller than the conductance of the second transistor 9B provided on the logic chip 7.

Specifically, the ratio of the conductance of the first transistor 9A to the conductance of the second transistor 9B can be equal to or less than 1/3 and can be more preferably equal to or less than 1/10.

Thereby, by decreasing the size of the first transistor 9A provided on each memory chip 6 and decreasing a drive current of the first transistor 9A, it is possible to reduce heat generation of each memory chip 6.

Accordingly, in the semiconductor apparatus 1 of the present embodiment, it is possible to increase the lamination number of memory chips 6 without changing a reflex cycle while reducing heat generation from each memory chip 6.

Further, in the semiconductor apparatus 1 of the present embodiment, the plurality of memory chips 6 and the logic chip 7 described above constitute the chip laminate body having a bumpless structure, and thereby, it is possible to reduce the thickness of the first semiconductor chip 2.

Specifically, the entire thickness of the first semiconductor chip (chip laminate body) 2 can be 40 to 200 μm, the thickness of each memory chip 6 can be 2 to 10 μm, and the thickness of the logic chip 7 can be 2 to 20 μm. Further, when the thicknesses of each memory chip 6 and the logic chip 7 is reduced, the entire thickness of the first semiconductor chip (chip laminate body) 2 can be reduced to 20 μm.

In the semiconductor apparatus 1 of the present embodiment, since the entire thickness of the first semiconductor chip (chip laminate body) 2 can be reduced, it is also possible to reduce the temperature difference that occurs between the memory chip 6 on an upper layer side and the memory chip 6 on a lower layer side. Thereby, it is possible to increase the lamination number of memory chips 6 without changing the reflex cycle.

The present invention is not necessarily limited to the embodiment described above, and various modifications can be made without departing from the scope of the present invention.

For example, the above embodiment is described using an example in which the present invention is applied to a semiconductor package referred to as an HBM; however, the embodiment is not necessarily limited to such a configuration. The present invention can be broadly applied to a semiconductor apparatus including a chip laminate body in which a plurality of memory chips are laminated on a logic chip that controls each of the plurality of memory chips.

What is claimed is:

1. A semiconductor apparatus, comprising
a chip laminate body in which a plurality of memory chips are laminated on a logic chip that controls each of the plurality of memory chips,
wherein the chip laminate body includes:
a plurality of penetration electrodes that penetrate through the plurality of memory chips and the logic chip in a thickness direction, and
a bumpless structure in which the plurality of memory chips and the logic chip are electrically connected together via the plurality of penetration electrodes without arranging a bump electrode in each space among the plurality of memory chips and the logic chip, and
a conductance of a first transistor provided on the plurality of memory chips is smaller than a conductance of a second transistor provided on the logic chip.

2. The semiconductor apparatus according to claim 1,
wherein a ratio of the conductance of the first transistor to the conductance of the second transistor is equal to or less than 1/3.

3. The semiconductor apparatus according to claim 1,
wherein a ratio of the conductance of the first transistor to the conductance of the second transistor is equal to or less than 1/10.

4. The semiconductor apparatus according to claim 1,
wherein a thickness of the chip laminate body is 40 to 200 μm,
a thickness of the memory chip is 2 to 10 μm, and
a thickness of the logic chip is 2 to 20 μm.

5. The semiconductor apparatus according to claim 2, wherein
a thickness of the chip laminate body is 40 to 200 μm,
a thickness of the memory chip is 2 to 10 μm, and
a thickness of the logic chip is 2 to 20 μm.

6. The semiconductor apparatus according to claim 3,
wherein a thickness of the chip laminate body is 40 to 200 μm,
a thickness of the memory chip is 2 to 10 μm, and
a thickness of the logic chip is 2 to 20 μm.

7. The semiconductor apparatus according to claim 1,
wherein the memory chip is a DRAM chip.

8. The semiconductor apparatus according to claim 2,
wherein the memory chip is a DRAM chip.

9. The semiconductor apparatus according to claim 3,
wherein the memory chip is a DRAM chip.

10. The semiconductor apparatus according to claim 4,
wherein the memory chip is a DRAM chip.

11. The semiconductor apparatus according to claim 5,
wherein the memory chip is a DRAM chip.

12. The semiconductor apparatus according to claim 6,
wherein the memory chip is a DRAM chip.
